(19) United States
(12) Patent Application Publication
(10) Pub. No.: US 2011/0120552 A1
(43) Pub. Date: May 26, 2011

(54) METHOD FOR PRODUCING A MONOCRYSTALLINE SOLAR CELL

(76) Inventors: Karsten Meyer, Erfurt (DE); Hans-Joachim Krokoszinski, Nussloch (DE)

(21) Appl. No.: 12/990,962

(22) PCT Filed: May 5, 2009
(86) PCT No.: PCT/EP09/55372

§ 371 Date: Jan. 24, 2011

(30) Foreign Application Priority Data
May 7, 2008 (DE) 10 2008 022 574.6
Jul. 15, 2008 (DE) 10 2008 033 169.4

(51) Int. Cl. H01L 31/0216; H01L 31/18

(52) U.S. Cl. 136/256; 438/89; 438/85; 257/E31.003; 257/E31.001

(57) ABSTRACT

A method for producing a monocrystalline solar cell having a passivated back side and a back side contact structure, having the following steps: applying a passivating dielectric layer onto the back side of the cell over the entire surface; removing the passivating layer locally in the area of bus bars and local contact locations; coating the back side of the cell homogeneously to develop an unpatterned, thin metal layer, which touches the surface of the substrate material in the areas free of the passivating layer; generating a thick layer from a conductive paste in the area of the bus bars and the local contact locations; and sintering of the thick layer at a temperature above a predefined eutectic temperature, and the formation of a eutectic, low-resistance connection of the thin metal layer to the surface of the substrate material as well as to the conductive particles of the thick layer paste.

### FIELD OF THE INVENTION

The present invention relates to a method for producing a monocrystalline solar cell having a passivated back surface and a back surface contact structure, as well as a cell of this kind produced according to this method.

### BACKGROUND INFORMATION

Silicon solar cells having a passivating antireflection layer on the front side n-emitter layer, may be furnished with a metallization over the entire surface of the base region for mirror coating and for band bending (back surface field—BSF) on the back surface.

Such a back side metallization is usually made up of an aluminum-based thick layer paste printed on over a large surface which, when sintered above 800° , alloys on by forming the melting-down AlSi eutectic and recrystallization on the semiconductor surface and, in the process, overcompensates for the n-doping present based on a phosphorus diffusion previously carried out for p⁺-doping.

Since contacts that may be soldered are also required on the back side, for the modular integration of cells, it is necessary to apply by printing, ahead of time, a silver-based paste, the print usually reproducing on the back side the number and the position of bus bars present on the front side. Such a cell of the related art is shown in the basic representation according to FIG. 1. The back side bus bars are printed in strip-shaped areas underneath the front side bus bars, before the final aluminum paste print fills up the remaining areas at the side of the bus bars, aluminum and silver along the edges of each silver stripe slightly overlapping.

The thick layer metallization could be replaced by a dielectric, mostly oxidic passivating layer, the electrical connection of the back side metallization to the semiconductor surface over a large surface being achieved by small point contacts (local back surface field—local BSF) situated mostly regularly in matrix positions.

The back side contact structure formed in this instance finds application in multiple variants, as described, for example, in A. W. Blakers et al, Appl. Phys. Lett., 55 (1989), pp. 1363 to 1365; G. Agostinelli et al, 20th European Photovoltaic Solar Energy Conference (2005), Barcelona, Spain, p. 647; and P. Choulat et al, 22nd European Photovoltaic Solar Energy Conference (2007), Milano, Italy.

The most widespread local BSF contacts are so-called “laser fired contacts” (LFC contacts), in which the metal layer previously applied by laser bombardment, usually developed as thin-film aluminum, is fused, all the way through the oxide layer, with the semiconductor surface.

One substantial disadvantage of the method of the laser-driven contacting is that the multiplicity of the necessary local contacts has to be produced sequentially, and therefore in as high a number as possible per second, and at high light intensity. During the high energy, point-by-point fusing of the aluminum all the way through the oxide layer that is created, there is frequently damage to the silicon surface under the local contacts, which shows itself especially in an increased surface recombination speed, and with that, a reduced passivating effect.

### SUMMARY

An object of the present invention to state a refined method for producing a monocrystalline solar cell, having a passivated back side and a back side contact structure, which specifies a protective and time-saving method for the production of a layer combination having the various functionalities for the local contacting of a solar cell back side.

Accordingly, an example method according to the present invention relates to a process step sequence for producing local contacts of a metal layer, all the way through a passivating layer that is over the entire surface of the back side of a cell, onto the semiconductor surface, in an inventive manner, the generation of a thin film being combined with the generation of a thick layer by screen printing or stencil printing. On account of the method sequence according to the present invention, a so-called PERC structure (passivated emitter and rear cell) is created, in this context, there being considerable advantages by contrast to the related art.

These advantages show up in that the passivating layer, which represents an electrical insulation at the same time, is able to be developed in each case from the most suitable material and using the technology that is most suitable in each case. This passivating layer is also able to be opened locally, using such a technology, that results in the least interactions with the remaining components. The passivating layer, in turn, is covered, using a protective technology, in particular, thin film technology, using a most suitable metallization, especially aluminum, at the same time as the large insulated surfaces, the local contact surfaces on the semiconductor surface also being covered.

The production of the local BSF surfaces from recrystallized AlSi in the local contact surfaces is combined with the sintering of a thick layer paste, especially a silver paste, which is applied ahead of time to the local contacts and the outer contact surfaces by printing. In this context, the melting of the AlSi eutectic is used in order to ensure a durable low-resistance connection of the thin film metallization on the passivating layer to the locally limited BSF layer in the semiconductor, via the AlSi eutectic's reaction with the conductive paste, particularly silver paste, which leads to the formation of intermetallic phases of the Ag—Al system.

The general steps of the method may be summarized as follows:

Applying a passivating, dielectric layer onto a usually preprocessed cell material, at least on the back side of the cell. Subsequently, a local removal of the passivating layer is undertaken in the area of bus bars and through-hole plating locations on the back side.

Thereafter, the back side of the cell is coated homogeneously, namely, for the formation of an unpatterned, thin metal layer which, in the areas free of the passivating layer, touches the surface of the substrate material, i.e., the semiconductor surface.

Then, the production of a thick layer is undertaken, from a conductive paste in the area of the bus bars and the through-hole plating locations.

There follows the sintering of the thick layer at a temperature above a predefined eutectic temperature, and the formation of a eutectic, low-resistance connection of the thin metal layer to the surface of the substrate material as well as to the conductive particles of the thick layer paste.

The previously mentioned passivating layer may be made of a silicon oxide, aluminum oxide or a similar material.

The thin film is generated preferably by sputtering or vapor deposition of an aluminum material.

The printed circuit traces and bus bars required on the front side may also be produced by thick layer screen printing or stencil printing.

Both thick layers, that is, the thick layer on the front side and the thick layer on the back side may be sintered during one common temperature treatment.

Pastes are selected for the thick layer implementation which preferably are able to be sintered in a temperature range above that of the Al—Si eutectic of 577° C., but below that of the aluminum melting point of 660° C., that is, preferably between 580° C. and 620° C.

### BRIEF DESCRIPTION OF THE DRAWINGS

The present invention is explained in greater detail with reference to an exemplary embodiment, as well as with the aid of the figures.

FIG. 1A shows a top view of a three bus bar standard cell.

FIG. 1B shows a cross section through a standard as in FIG. 1A.

FIGS. 2A-E show sectional representations to illustrate an example method sequence, according to the present invention, for producing the new type of solar cell having back side contact structure (passivated back side having local contacts PERC).

### DETAILED DESCRIPTION OF EXAMPLE EMBODIMENTS

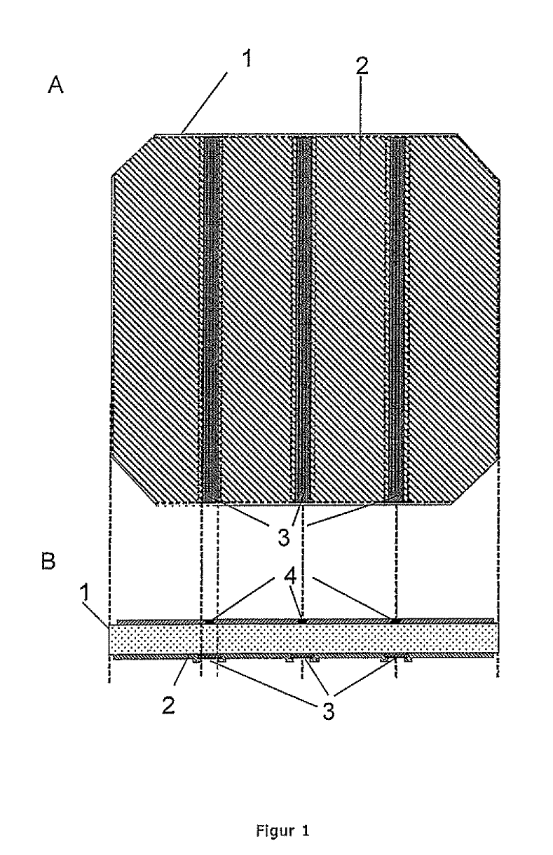

FIGS. 1A and 1B show the top view, or rather a cross sectional representation of a three bus bar standard cell made of a p-silicon wafer 1 having bus bars on the front side 4, as well as back side bus bars 3 and an aluminum paste print filling the remaining surfaces 2 at the side of the bus bars, aluminum and silver along the edges of each silver stripe slightly overlapping (see cross section as in FIG. 1B).

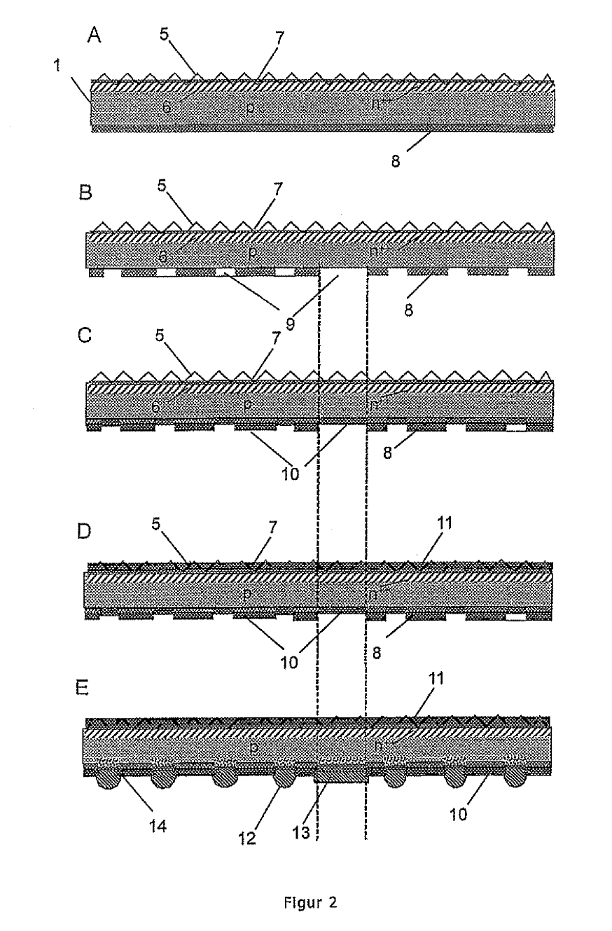

In the method according to the sequence as in FIGS. 2A through E, in a first process step, the deposition is undertaken of a dielectric passivating layer 8, e.g., silicon oxide, on the back side, by thermal oxidation, for instance, LPCVD, PECVD, sputtering or the like. The front side has a front side texture 5 as well as an antireflection layer 7. Base material 1 is a p-silicon wafer having an n⁺⁺-emitter 6.

In the first step for generating the passivating layer, if thermal oxidation has taken place, one should take care that there is an additional etching removal of the oxide on the front side.

In the process step according to FIG. 2B, a local removal takes place of passivating layer 8 on the back side in the area of the bus bars and at all local through-hole plating locations or through-hole plating points 9, e.g., by laser ablation, the printing of etching paste or by plasma etching.

According to the illustration in FIG. 2C, a homogeneous coating of the back side is carried out using a conductive material, especially an aluminum-containing thin film 10, by vapor deposition or sputtering.

In the process step as in FIG. 2D, screen printing of the printed circuit traces and bus bars takes place on the front side, for instance, with the aid of a conductive paste, especially using silver paste 11.

According to the illustration in FIG. 2E, the application of through-hole plating points 12 and bus bars 13 on the back side of the cell also takes place in screen printing, namely by recourse to silver paste material.

In a last process step according to FIG. 2E, sintering takes place of all screen printing pastes, that is, the developed traces on the front side and through-hole plating points 12 and bus bars 13 on the back side, in a temperature range between 580° C. and 620° C. During this process, because of the sintering temperature above the eutectic temperature of 577° C., a low-melting AlSi eutectic 14 forms in the contact surfaces between the silicon and the aluminum layer. At the same time, the silver particles of the silver paste alloy with the liquid aluminum-silicon eutectic, because during sintering the aluminum-silver eutectic temperature of 566° C. is also exceeded.

The present invention representing its method features also extends to so-called MWT cells (metal wrap through), in which emitter fingers are situated on the front side and emitter bus bars are located on the back side, and emitter fingers and emitter bus bars, in this instance, are in electrical connection via metallized holes that are bored by laser or are similarly bored.

1-10. (canceled)

11. A method for producing a monocrystalline solar cell having a passivated back side and a back side contact structure, comprising:
applying a passivating dielectric layer onto a back side of the cell over an entire surface;
removing the passivating layer locally in an area of bus bars and local contact locations;
coating the back side of the cell homogeneously to develop an unpatterned, thin metal layer, which touches a surface of the substrate material in areas free of the passivating layer;
generating a thick layer from a conductive paste in the area of the bus bars and the local contact locations; and
sintering the thick layer at a temperature above a predefined eutectic temperature, and forming a eutectic, low-resistance connection of the thin metal layer to the surface of the substrate material and to conductive particles of the thick layer paste.

12. The method as recited in claim 11, wherein the passivating layer is made up of one of silicon oxide, aluminum oxide, silicon nitride, silicon carbide, silicon oxide-silicon nitride layer sequences, amorphous silicon and silicon nitride, or comparable materials with respect to their properties.

13. The method as recited in claim 11, wherein the thin film is formed by one of sputtering or vapor deposition of an aluminum-containing material.

14. The method as recited in claim 11, wherein, on a front side of the cell, printed circuit traces and bus bars are produced by one of thick layer screen printing or stencil printing.

15. The method as recited in claim 11, wherein the thick layer in the area of the bus bars and the local contact locations is produced on the back side by one of screen printing or stencil printing.

16. The method as recited in claim 15, wherein the thick layers are sintered in one common temperature treatment step.

17. The method as recited in claim 16, wherein the sintering is carried out in a temperature range between 580° C. and 660° C.

18. The method as recited in claim 16, wherein the sintering is carried out in a temperature range between 580° C. and 620° C.

19. The method as recited in claim 11, wherein the conductive paste contains silver.

20. The method as recited in claim 11, wherein the sintering of the thick layer takes place at a temperature above an aluminum-silicon eutectic temperature of 577° C., but below an aluminum melting point of 660° C.

21. A solar cell, having a passivated back side and a back side contact structure, the cell being produced by applying a passivating dielectric layer onto a back side of the cell over an entire surface; removing the passivating layer locally in an area of bus bars and local contact locations; coating the back side of the cell homogeneously to develop an unpatterned, thin metal layer, which touches a surface of the substrate material in areas free of the passivating layer; generating a thick layer from a conductive paste in the area of the bus bars and the local contact locations; and sintering the thick layer at a temperature above a predefined eutectic temperature, and forming a eutectic, low-resistance connection of the thin metal layer to the surface of the substrate material and to conductive particles of the thick layer paste.
